(19) United States
(12) Patent Application Publication
(10) Pub. No.: US 2011/0260749 A1
(43) Pub. Date: Oct. 27, 2011

(54) SYNCHRONOUS LOGIC SYSTEM SECURED AGAINST SIDE-CHANNEL ATTACK

(76) Inventors: Alexander Roger DEAS, Dalkeith (GB); David COYNE, Glenrothes (GB)

(21) Appl. No.: 13/094,022

(22) Filed: Apr. 26, 2011

(30) Foreign Application Priority Data
Apr. 26, 2010 (GB) 1006911.0

(51) Int. Cl. H03K 19/003

(52) U.S. Cl. 326/8

(57) ABSTRACT

An improvement in the security of a logic system from attacks that observable features such as the power supply or electromagnetic radiation, so called, “side-channel attacks”. Specifically, the present invention comprises a technique and method for reducing ability to monitor the relationship between currents in the system and the data in the system by closing the overall clock eye diagram, whilst keeping the eye diagram for connected stages open. The degree of eye closure for connected pipeline stages allows the system to run closer to its maximum operating speed compared to the use of system wide clock jitter, yet the overall closure provides security that is absent from systems with a partially open eye.

### BACKGROUND OF THE INVENTION

1. Technical Field

The present invention relates to providing security to a logic system from attack through monitoring of observable features such as the power supply or electromagnetic radiation, in so called “side-channel attacks”. A side-channel attack may seek to obtain information concerning the contents of the system, such as a private key or crypto-engine data.

Any system that has a partially open clock data eye is susceptible to side-channel attack. It is not sufficient to close the eye partially: it must be filly closed to be secure. It is also not sufficient to add noise to a clock or data emitter to disguise the signal: statistical analysis of a noisy eye can determine very quickly what the data is with the noise removed. For a system to be secure from side channel attack, the emissions must be completely random, and this requires a closed clock eye diagram. Attempts described in the prior art all leave an open, or partially open, clock eye diagram. Reports that a synchronous system with a partially open clock eye diagram is resistant to attack has been due to limits in the abilities of the attacker rather than a formal basis for reliance on the system as being secure. For a provably secure system, the observable clock data eye must be closed.

### BACKGROUND OF THE INVENTION

Many logic circuits at this time are implemented in standard CMOS where the techniques for design of such logic circuits are well known. It is typical that in the design of standard CMOS logic circuit elements current is drawn from the positive supply when the output of the logic circuit element changes from a logic-0 state to a logic-1 state. As an example a typical CMOS inverter may consist of a PFET and a NFET, the source of the PFET connected to the positive supply, the drain of the PFET connected to the output, the gate of the PFET connected to the input, the source of the NFET connected to the negative supply, the drain of the NFET connected to the output and the gate of the NFET connected to the input. The PFET and NFET are generally implemented as enhancement mode devices. Typically the load on the output of a CMOS inverter is a capacitor comprising parasitic capacitance due to the routing of the output signal to other logic gates and input capacitance of other logic gates. A logic-0 state applied to the input of the CMOS inverter will turn on the PFET, turn off the NFET and charge any capacitance on the output raising the output voltage to a logic-1 state. A logic-1 state applied to the input of the CMOS inverter will turn off the PFET and turn on the NFET forcing the output voltage to the negative supply generating a logic-0 state. Current flows from the positive supply into the output load of the CMOS inverter when the input changes from a logic-1 state to a logic-0 state. Current flows from the load of the CMOS inverter when the input changes from a logic-0 state to a logic-1 state. Current may also flow from the positive supply to the negative supply when the CMOS inverter changes state due to a period when both the PFET and NFET may be both turned on. In a highly synchronous system where many logic elements change state under direction of a clock current peaks may be detectable in the system supply current. It is these current peaks that may enable an observer to determine aspects of the system design that the system designer would rather remain private for reasons of security.

A typical example of where covert monitoring of the power supply current may reveal information to a third party is in smartcard security. Smartcards employ encryption techniques to ensure that neither a PIN number or an encryption private key is revealed to a third party. The key in the encryption scheme has been shown to be readable by monitoring smartcard power supply current. Techniques known as simple power analysis, differential power analysis and higher order differential power analysis have been used to reveal the private encryption key, thereby rendering the security worthless.

It is not always necessary to use such an intrusive technique such as breaking the power supply connections of a smartcard and monitoring the electrical current flow. Electromagnetic emissions occur as a result of current flow and may also be monitored to reveal the temporal position of current peaks.

It has been explained that in standard CMOS logic gates as employed in an integrated circuit current peaks occur in the positive supply current when the output signal of a logic gate transitions from a logic-0 state to a logic-1 state. One attempt [U.S. Pat. No. 6,327,661] uses random noise generation and clock skipping to randomise the position of current peaks. Any form of introduction of random noise or changes in the clock rate will reduce the maximum data rate that can flow through the encryption engine. Such techniques also results in an increase of current consumption.

Another attempt [U.S. Pat. No. 6,507,130] to improve security relies on switching off the external supply during security-conscious operations and connecting to an internal capacitor which had previously been charged from the external supply. This method suffers from the requirement to have an on-card capacitor which may present a problem in terms of the card form-factor. The other problem with this approach is that it makes it possible to monitor the emissions from the capacitor using near field probes, which are nicely identified for the attacker simply by the switch in power.

Another attempt [U.S. Pat. No. 6,766,455] uses a zener diode and bipolar transistor as a rudimentary linear supply voltage regulator to isolate the internal supply and thereby current peaks from exiting the system. This method suffers from increased power consumption as well as not being suitable for the highest level of integration by using components that are non-standard in VLSI standard CMOS processes. There are other disadvantages and weaknesses created by this method. Another attempt to make it more difficult to determine the internal workings of an integrated circuit is to use differential logic gates [IEEE Proceedings, ISCAS 2005, Low Power Current Mode Logic for Improved DPA-Resistance In Embedded Systems, Toprak and Leblebicic]. In differential logic gate there exists a true output and a complementary output, one of said outputs always generating a current spike in the positive supply when an output transition occurs.

Another attempt [U.S. Pat. No. 7,417,468] of reducing the current spikes is to employ specialised logic gates that have differential outputs, the differential outputs being reset to logic-0 and then pre-charged to a logic-1 prior to evaluation of the final logic output level. Again, current peaks occur at every logic transition.

Another attempt to de-correlate current peaks and logic state transitions [IEEE Proceedings, ISCAS 2005, A Novel CMOS Logic Style with Data Independent Power Consumption, Aigner et al] relies on using ternary logic levels.

The above methods have been shown to have some effect in improving the security of the integrated circuit in resisting attempts to obtain knowledge of the integrated circuit operation or contents. However, all of these methods rely on one or more of the following; balancing edge speed of the inputs, generating equal delays for the true output and complementary output rising edges, and balancing the load capacitance which also includes balancing the routing capacitance. Any imbalance reduces the effectiveness of the differential gate in generating constant amplitude current spikes thereby allowing an intruder to simply increase the complexity of the averaging algorithm to obtain the knowledge sought. These differential systems can be compromised simply by reducing the supply voltage to the point where the differential pair saturates.

Varying the supply voltage, varying the clock frequency or varying both the supply voltage and clock frequency have been shown an increase in resistance to intruder attacks [DATE 2005, Power Attack Resistant Cryptosystem Design, A Dynamic Voltage and Frequency Switching Approach, Yang et al]. The improvement comes from the voltage variation, due the way it is implemented. The method takes a lot of power as it is a linear power supply, and it has a high bandwidth. Near field probing of the supply can detect the feedback to the supply, providing the current information. The technique relies on the use of a linear power supply that may be modulated rapidly in time which may require custom designed cells not available in many standard CMOS processes. Yet further, the use of linear power supplies implies increased current consumption.

Methods that try to prevent power analysis by random frequency variations of a single clock can be comprised both by statistical analysis of the operation of the system on known plain text, or just by synchronizing the power monitor to the clock edge.

A common issue with all of the above methods is that there may be one or more penalties associated with the implementation namely power consumption, circuit processing speed or area increase. There is a need for a method to increase the resistance of an integrated circuit to intruder attacks with minimal penalty of speed, area or power consumption.

It is noted that in order for an intruder to successfully attack an integrated circuit the intruder is required to align multiple power consumption or current consumption traces and perform statistical analysis on the data. Randomising the position of current peaks reduces the ability of the intruder to align successive power consumption or current consumption traces.

Changing the clock frequency can move the position of current peaks associated with logic state changes temporally. However, it is obvious that in order to modulate the clock frequency it is necessary to operate the system at a lower overall frequency which is not generally beneficial. Further, in order to modulate the temporal position of current peaks over a wide time it is necessary to lower the clock frequency significantly which has ramifications on the overall performance of a system. Consider a synchronous logic system comprising of D-type flip-flops (DFF's) where a signal path exists between two DFF's passing through a block of combinatorial logic. The highest frequency that the system can be clocked is dependent to a large extent on the maximum propagation delay through the combinatorial logic. In a state-of-the art system where it is desired to operate the logic system at the highest possible clock speed the clock period is chosen so that it is slightly larger than the worst-case propagation delay through the combinatorial logic. Any attempt to modulate the clock to move the current peaks associated with state transitions within the logic system will require that the average clock speed is reduced. It is desirable that the system clock operates at the highest frequency for highest performance. It is also desirable that current peaks are moved well away from their nominal temporal position in order to make side channel attacks more difficult. These two desires are at odds with one another. It has thus been shown that it is desirable to be able to modulate the system clock with minimal impact to the speed of the logic system.

In a synchronous system such as shown in FIG. 2, applying large amounts of clock modulation lowers the operating speed. Consider a synchronous logic system as in FIG. 2 where the maximum delay between any two states of the system is, for example, 20 ns—assume that this figure includes not just the combinatorial path delay but the delays inherent to correct DFF operation. With such a worst-case delay it is possible to operate the synchronous system at clock speeds up to 50 MHz. However, if it is desired that the clock eye be closed 80% i.e. the clock is modulated ±40% then the clock period must be increased so that this eye opening represents the worst-case delay. Accordingly the clock period must be increased to 100 ns i.e. a reduction in operating frequency from 50 MHz to 10 MHz which is a significant penalty in operational speed. FIG. 4 shows an eye diagram where the clock is modulated ±40% of the clock period resulting in an eye opening of 20 ns. In this example the current peaks are moved over a large portion of the clock period and security is improved. It is beneficial to avoid large reductions in clock speed when modulating the clock to randomise the temporal position of current peaks in a synchronous logic system.

Any systems with either internal clocks, or an external clock supplemented by an internal clock for the encryption engine can be compromised using a very near field probe. This form of attack is simplified by the packaging of smartcards, which generally used linished die, i.e. very thin due, and the rear surface is accessible after removing a local part of the package.

FIG. 3 shows the eye diagram of a clock signal that is modulated, either randomly or in a pre-defined manner. The clock has a period of one unit and is modulated randomly ±2% of the clock period. This is a typical figure for spread-spectrum clock generator chips commonly available, such as Cypress Semiconductors Corporation CY25811 spread-spectrum clock generator integrated circuit. It is clear that as the amount of modulation is small then so too is the amount of movement of the current peaks. The amount of modulation in spread-spectrum clock generator chips is generally kept quite low so the designer of an integrated circuit or system does not have to guard-band the logic timing budget and not impact the maximum operating frequency. However, from a security perspective the use of such a low amount of modulation has little impact on improving the security.

Each foregoing prior art counter-attack methods has one or more of the following drawbacks in an integrated circuit or other physical implementation of an encryption engine: insufficient protection, large physical size, high power consumption, non-standard design flow, library availability to the implementation of a robust and practical encryption engine with high immunity to attack through simple, differential power analysis or higher order differential power analysis.

Any system employing a spread spectrum clock can be comprised easily because the statistical eye diagram for the clock can never be closed. It must be open at least as wide as the maximum propagation path between two registers.

### Object of the Present Invention

It is an objective of the present invention to reduce the sensitivity of logic systems to comprise from monitoring externally observable features, i.e. side channel attacks.

It is a further objective of the present invention to randomise the current peaks associated with state transitions to such an extent that the effective clock eye diagram is closed to form a noise mask

It is a further objective of the present invention to provide a synchronous logic system wherein the clock frequency reduction associated with randomising the clock transitions is maintained at a high proportion of the maximum clock frequency.

It is a further objective of the present invention to provide a clocking scheme for a synchronous logic system with improved security.

It is a further objective of the present invention to support design flows that can be implemented using standard CMOS libraries

### BRIEF SUMMARY OF THE INVENTION

The present invention relates to techniques and a method that uses multiple clock signals within a synchronous logic system to randomise the temporal position of current peaks associated with state changes at clock edges. This is achieved by applying a different clock to pipeline stages, such that the clock eye is open between two connected pipeline stages, but is closed over the whole pipeline.

Stages of the synchronous logic system are arranged in a pipeline which is common among algorithmic and structured synchronous logic systems, each stage of the pipeline being driven by a separate clock phase, where there is a random relationship between clock phases, that the clock eye diagram for each two connected stages is open, but for the pipeline the clock eye diagram is closed.

The randomisation of the clock edges improves the resistance of the synchronous logic system to attack methods such as power supply current monitoring, electromagnetic field monitoring or very field monitoring, as a means to gain an insight to the operation or contents of the system. When the effective clock eye diagram is closed by random jitter, there is provably no data content in the side-channels (current in the power supply, or electromagnetic emissions from the system).

A clock generator is used to provide a source of multiple clocks with a plurality of those clocks randomly modulated such that the effective clock eye diagram of the combination of all clock signals may be closed or tends towards closure.

Each successive pipeline stage has a clock eye that is open, and the overall reduction in the maximum clock frequency of the system due to a reduction in the overall clock eye by the introduction of jitter can be much with than other techniques, enabling the system to run faster at the same level of security.

### BRIEF DESCRIPTION OF THE DRAWINGS

For a better understanding of the present invention and the advantages thereof and to show how the same may be carried into effect, reference will now be made, by way of example, without loss of generality to the accompanying drawings in which:

FIG. 1 shows a diagram of part of a synchronous logic system with multiple clock phases employed in the present invention.

FIG. 2 shows a diagram of a prior art synchronous logic system employing a single phase clock.

FIG. 3 shows an eye diagram of a prior art synchronous logic system employing a single clock with clock modulation running close to the maximum operating frequency.

FIG. 4 shows an eye diagram of a prior art synchronous system employing a single clock with a large amount of clock modulation resulting in a lower operating frequency.

FIG. 5 shows part of a synchronous logic system as disclosed in the present invention with pipelined stages and multiple clocks.

FIG. 6 shows part of a synchronous logic system as known in prior art with multiple pipelined stages and a single clock.

FIG. 7 shows a timing diagram of a prior art synchronous logic system employing a single phase clock.

FIG. 8 shows a timing diagram of a prior art synchronous logic system where a modulated clock is used to randomise the current peaks associated with clock transitions.

FIG. 9 shows an eye diagram of the clock in a prior art synchronous logic system depicted in FIG. 8.

FIG. 10 shows a timing diagram of a synchronous logic system with multiple clock phases employed in the present invention.

FIG. 11 shows eye diagrams of the individual clocks and effective composite clock of the present invention.

FIG. 12 shows a means of generating multiple phase clocks as disclosed in the preferred embodiment of the present invention.

### DETAILED DESCRIPTION OF THE INVENTION

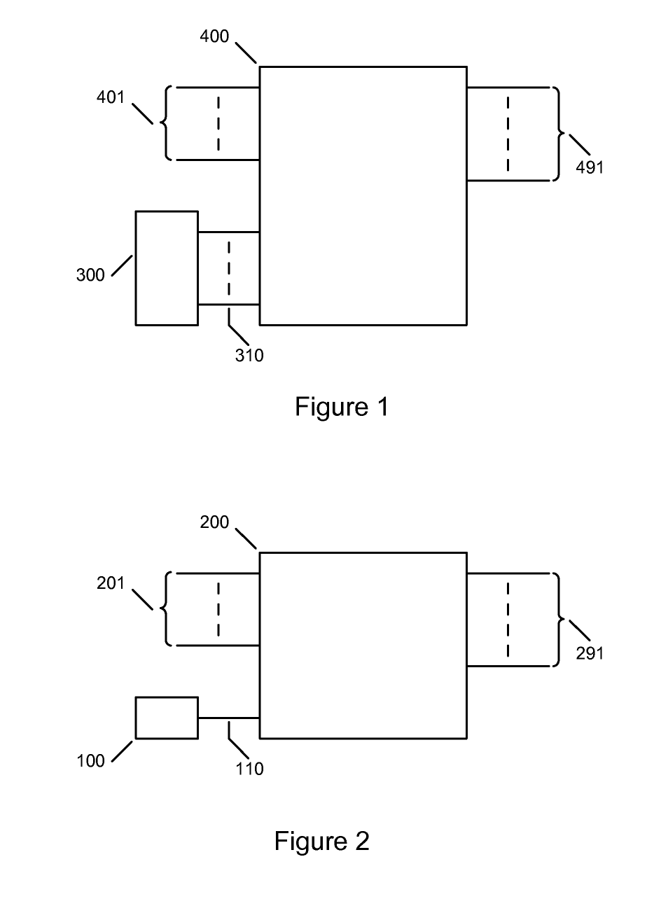

FIG. 1 shows a diagram of a synchronous logic system with multiple clock phases employed in the present invention. Clock generator 300 produces a plurality of clocks 310 for logic system 400. Logic system 400 has data inputs 401 and data outputs 491 said data outputs changing in response to data inputs 401 in a well-defined manner based on present and past data inputs 401 typically at clock 310 transitions. As a generality the present invention will refer to rising edge clock transitions but it is clear that such logic systems can employ operate on falling edge clock transitions or both rising and falling clock edge transitions.

FIG. 2 shows a diagram of a synchronous logic system with a single phase clock as used in prior art. Clock generator 100 produces a single clock 110 for logic system 200. Logic system 200 has data inputs 201 and data outputs 291 said data outputs 291 changing in response to data inputs 201 in a well-defined manner based on present and past data inputs 201 typically at clock 110 transitions. Where the synchronous logic systems depicted in FIG. 2 employ standard CMOS logic gates both systems will produce current peaks that may enable decryption of the internal operations that are required to remain secret. As previously shown modulating the clock will result in a lower operating speed of the system which is not desirable. One measure of the effectiveness of modulating the clock is to observe the eye diagram produced by the clock. An eye diagram that is closed may be considered as being more randomly modulated and is highly resistant to monitoring.

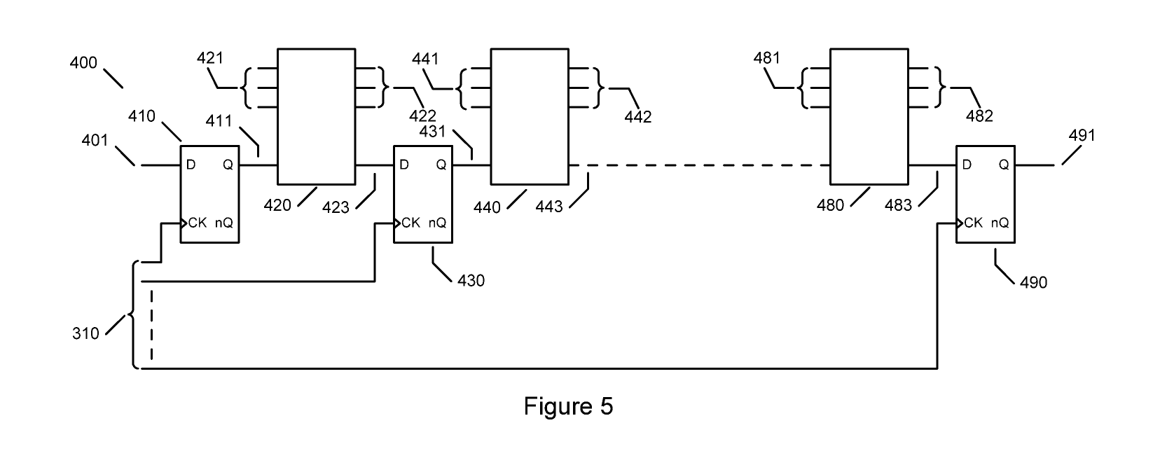

FIG. 5 shows a circuit diagram of part of a synchronous logic system that may be deployed in the synchronous logic system of FIG. 1 as a preferred embodiment of the present invention. Such a synchronous system may compromise, but is not limited to, a plurality of D-type flip-flops (DFF's) 410, 430 etc, blocks of combinatorial logic 420, 440 etc and a plurality of clock sources 310. In other embodiments of a synchronous logic system other logic elements such as JK flip-flops and/or other state storage elements known to someone versed in the art of logic design may be employed.

A state storage element is characterised by one or more input signals, one or more output signals and, typically, a clock. A DFF is typical of a state storage element and is characterised by a single input signal to the D pin whereby the output signal Q takes on the value of the D input signal when the clock transitions, typically, from a logic-0 to a logic-1 state. The DFF may also have an additional output, designated nQ in this disclosure, which takes on the complementary value of the Q signal. The DFF may also have other input signals such as a set signal and/or a reset signal which may be used to initialise the DFF outputs into a preferred state e.g. as part of a power-up initialisation sequence. These additional signals may operate synchronously i.e. in conjunction with the clock transitions or asynchronously i.e. independent of the state of the clock or transitions in the clock signal.

In a typical synchronous logic system there may be a plurality of input signal's applied to a plurality of DFF's. Similarly a typical synchronous logic system may have a plurality of output signals. Without generalisation FIG. 5 shows part of a synchronous logic system with a single input signal 401 applied to DFF 410 producing DFF output signal 411 on the application of a rising edge of one of clock signals 310. DFF output 411 is passed through combinatorial logic block 420. Combinatorial block 420 has multiple input signals 411 and 421 and multiple output signals 422 and 423. Combinatorial block 420 generates output signals 422 and 423 which may be described by Boolean combinations of the input signals 411 and 421. Output signal 423 of combinatorial logic block 420 is presented as an input to DFF 4430 where the logic state of said signal is stored on the application of a rising edge of another signal from clock signals 310, this clock signal different to clock signal clocking the first stage DFF 410. This process continues through a plurality of DFF's and combinatorial blocks to produce a final output signals including output signal 491.

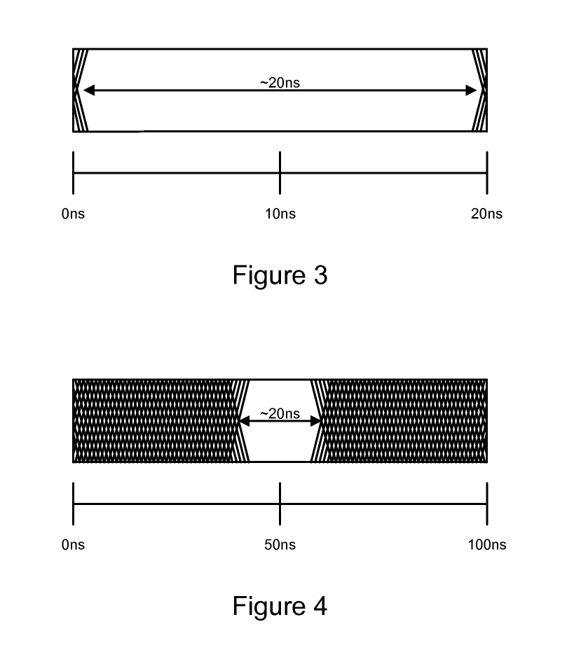

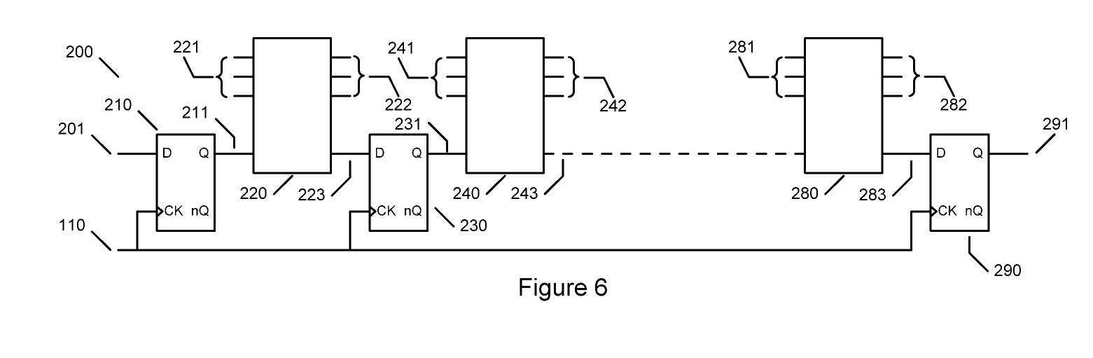

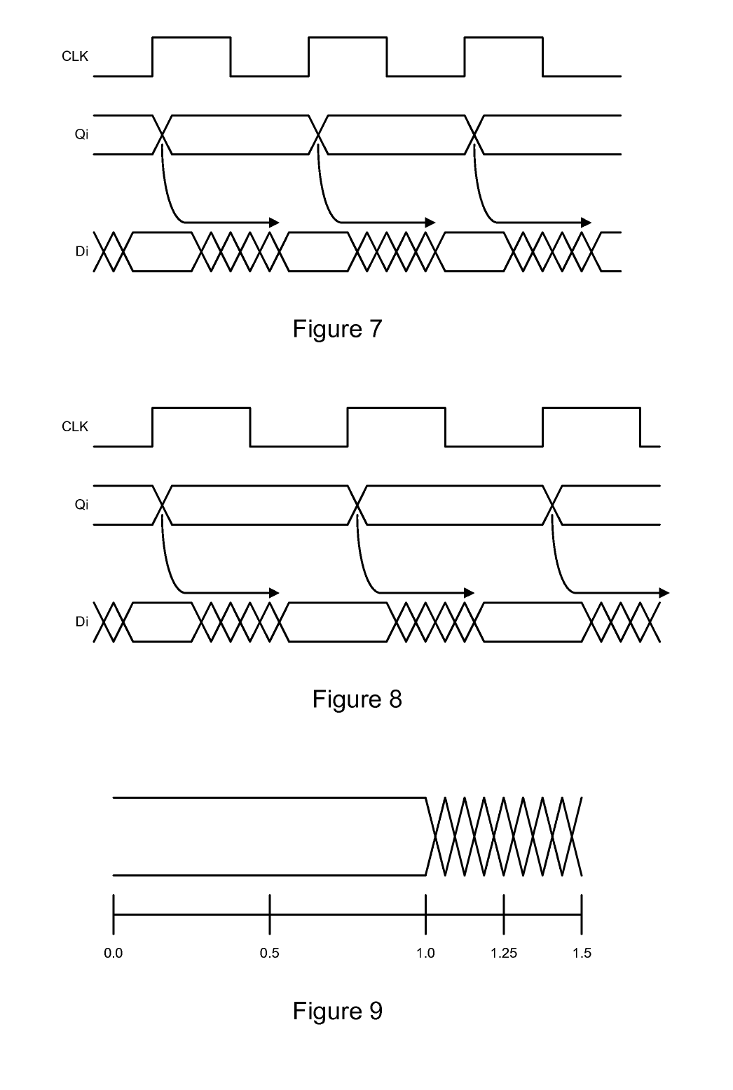

FIG. 7 shows, in part, the timing of a synchronous logic system such as shown in FIG. 6 wherein a single clock is utilised. The delay through the combinatorial block is again significantly larger than the delays associated with the DFF. The timing diagram of FIG. 3 shows a clock signal 110, the output signal of a first DFF 211 and the output signal of a combinatorial block 223, which is the input signal to a second DFF 230. From the rising edge of signal CLK 110 a first DFF 210 generates output signal Qi 211 which is further input to combinatorial block 220, where combinatorial block 220 produces signal Di 223 to the input of second DFF 230. It is shown that signal Di 223 at the input to second DFF 230 is stable just before the arriving edge of clock signal 110, the signal having been generated as a result of a state change at the output of first DFF 210 in response to a first rising edge of clock 110, the delay from the first rising edge of clock 110 being dominated by the propagation delay through combinatorial block 220. Thus synchronous logic system 200 is depicted as operating at the highest frequency possible.

FIG. 8 depicts a timing diagram for synchronous logic system 200, similar in appearance to FIG. 7, wherein the clock period is increased to facilitate the implementation of randomised clocking. In this example the clock period is increased by 25% showing that the stable sampling point of the Di 223 input signal is widened. This allows the period of clock 110 to be varied temporally thereby moving any supply current peaks associated with transitions in DFF output signal 211 to be similarly moved in time. FIG. 9 shows the eye diagram associated with a modulation of a clock where the nominal clock period has been increased by 25% and a random modulation of ±20% (relative to the increased nominal clock period) is further applied to the clock. It can be seen in FIG. 5 that the clock period is actually increased to 50% over the original clock period due to the total clock period having to be larger than the modulation. The eye diagram is open for 66% of the modified nominal clock period. With the instantaneous clock modulation such that the period between rising clock edges is at the minimum value the period between rising clock edges is still sufficient to allow the complete propagation of the slowest signal through the combinatorial block. Increasing the clock period further does allow the modulation to be increased closing the clock eye diagram further and spreading current peaks across a wider time period. In a conventional synchronous logic system with a single clock phases it is not possible to completely close the clock eye diagram due to the necessity of maintaining a window equal to the maximum propagation delay between DFF's. It would be desirable to close the clock eye as much as possible but this can only come at the expense of a reduction in the speed of the overall clock speed and latency of the system.

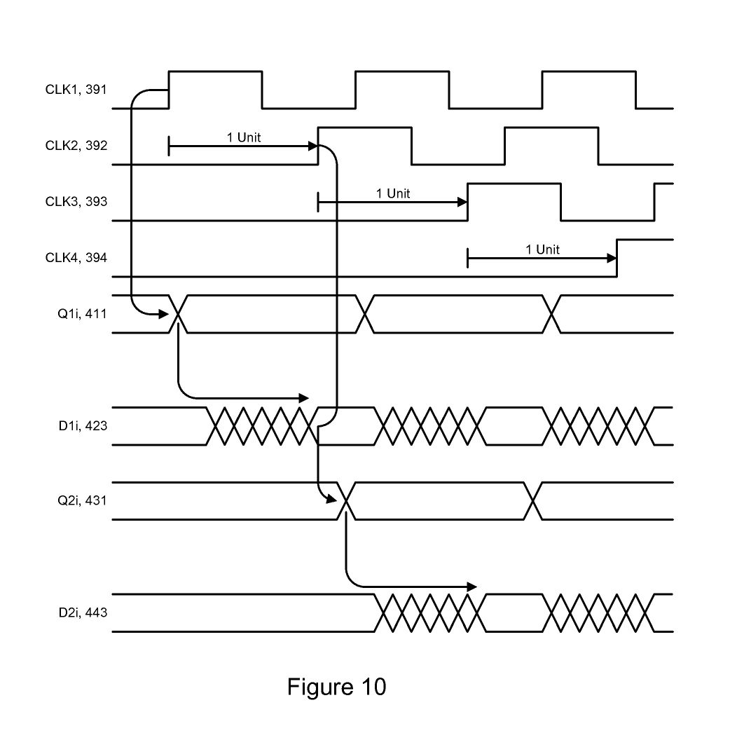

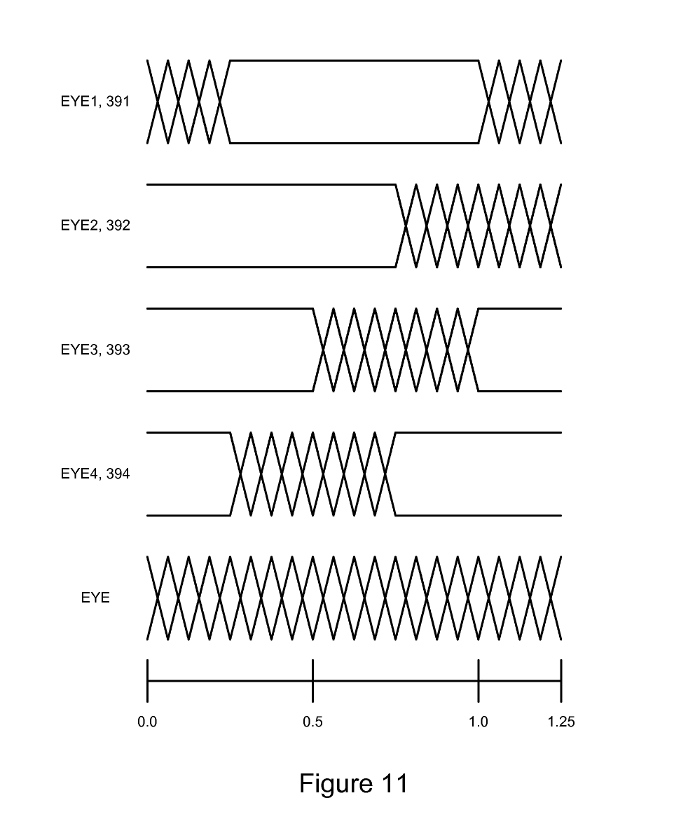

FIG. 10 shows a timing diagram of some of the signals employed in one embodiment of the present invention. The timing diagram shows the multiple clocks 391, 392, 393 and 394 in clock bus 310. For reasons of clarity the clock signals are not shown with modulation. Further, for reasons of clarity the clocks are normally running continuously but are shown in the timing diagram as though they have just started. The timing diagram shows clock signal 391 applied to DFF 410 producing output signal 411 and combinatorial block output signal 423. The timing diagram in FIG. 10 also shows the phase relationship between the multiple clocks 391, 392, 393 and 394. In a preferred embodiment of the present invention the clocks are separated by a delay of 1.0 time unit where the nominal clock period, without modulation, is set to 1.25 time units. FIG. 11 shows the eye diagram of each clock signal 391, 392, 393 and 394 as well as a composite eye diagram for the combined clocks. It can be seen with the clock period, clock modulation and clock delay parameters chosen the clock eye diagram is closed. It is obvious to someone practiced in the art that other modulation parameters may be used to vary the effective clock eye diagram.

In FIG. 1 clock bus 310 comprises clocks 391, 392, 393 and 394 produced by clock generator 300. Clock generator 300 may take as input a clock or, alternatively, generate a clock internally. The clocks are shown herein as being equally spaced in time relative to the first clock edge but, without loss of generality, may be otherwise arranged as is discussed later in this disclosure.

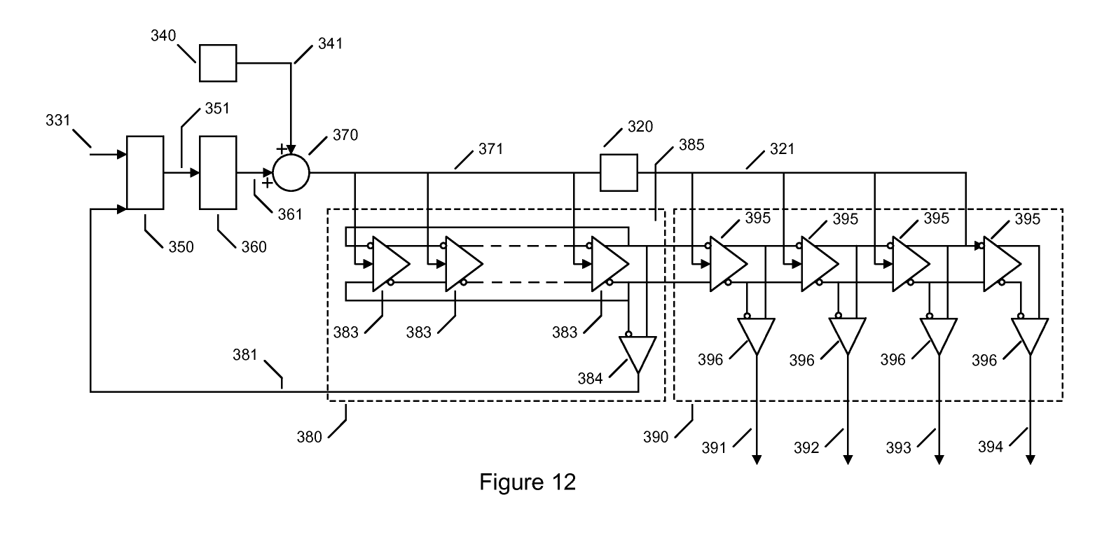

One embodiment of clock generator 300 is shown in FIG. 12 and comprises common elements found in a phase locked loop; phase detector 350, charge pump and loop filter 360 and voltage controlled oscillator (VCO) 380. Clock modulation source 340 is used to randomise the output of clock generator 300 while delay line 390 is employed to generate the multiple clock signals.

In an alternative embodiment of clock generator 300 the phase locked loop components may be dispensed with and an alternative oscillator used to produce the clock signal input to the delay line, for example a relaxation oscillator or an inductor-capacitor based oscillator. The delay line could then be built from components used in the alternative oscillator to provide timing constant with process, voltage or temperature changes.

By means of an example, but not restricted to, a phase locked loop is used to describe one means of generating a clock signal with a random content. Clock signal 331 is a first input to phase detector 350. VCO output 381 is a second input to phase detector 350. Phase detector 350 produces one or more output signals 351 to charge pump 360 carrying information about the phase difference between the first phase detector input signal and second phase detector input signal, said signal or signals being in digital form. Charge pump and loop filter 360 produce a linear output voltage or current 361. Signal 361 is, generally, linearly related to the difference in phase between clock input 331 and VCO output 381. Clock modulating source 340 produces an output 341 that is used to modulate the clock frequency, being combined with the charge pump/loop filter output signal 361 by summer 370. Summer 370 produces output signal 371 which is connected to the VCO 380 control input. By means of an example the VCO is shown as a plurality of differential inverter stages connected as a ring oscillator. It is clear to someone practised in the art that other embodiments of the phase locked loop and constituent components are possible including the use of an XOR phase detector, the use of differential charge pump and loop filter, the use of other types of VCO including but not limited to oscillators containing passive elements such as inductors, resistors and capacitors as well as active elements such as bipolar transistors and/or MOS transistors.

A first output of VCO 380 is converted to single-ended signal 381 with converter 384 and fed back to phase detector 350 second input. A second output of VCO 380 is maintained as differential signal 385 which serves as input to delay line 390. Delay line 390 comprises a cascade of delay elements 395 of the same design or of similar design to VCO delay elements 383 similarly controlled by VCO control signal and summer output signal 371 or some other control signal in an alternate clock generator scheme that does not use a phase locked loop. The delay produced by delay elements 395 is maintained at a constant fraction of the VCO frequency. Filter 320 is employed to filter out higher frequency variations of the modulated VCO control signal 371 producing a separate control signal 321 for delay elements 395 which is relatively unaffected by the modulating signal. The delay elements produce a plurality of clock signals, in a preferred embodiment of the clock generator four clock signals are produced, spaced in time by the delays associated with delay elements 395. Output converters 396 convert the delay line outputs into CMOS signals for use with standard CMOS logic cells in synchronous logic system 400.

In a preferred embodiment of the present invention the delay period between multiple clock signals 391, 392, 393 and 394 produced by delay line 390 are equal to or slightly greater than the maximum propagation delay of the conventional implementation of the synchronous logic system. By means of an example all times are now referenced to a conventional logic system with a single phase clock wherein the minimum clock period of said system is set by the maximum propagation delay between clock stages. The minimum clock period is then said to be 1.0 time units. The term “time units” is used rather than absolute frequency to show that the present invention is not limited to a fixed frequency or range of frequencies. Neither is the present invention limited in scope to these delays or modulation amounts within the constraints of maintaining sufficient timing margin at the DFF inputs.

In a preferred embodiment of the present invention the clock period is set to a nominal value of 1.25 time units with the delay between the clock signals 391, 392, 393 and 394 set to 1.0 time units. The clock is modulated randomly with a modulation of ±0.25 time units which results in a closed eye diagram for the composite clock of all clock signals overlapping modulo-1.25.

One issue arising with the present invention is the requirement to insert delays in signals that are fed back from one clock phase to another clock phase. For example, to feed a signal back from a DFF clocked by CLK3, 393 to a DFF clocked by CLK1, 391 it is necessary to introduce a delay in the signal path equal to twice the modulation time. This ensures that the setup time is correctly maintained. In a further embodiment of the present invention the clocking scheme where more than four pipeline stages are present the clocks are replicated with CLK1 391 driving the 5^{th} stage, CLK2 392 driving the 6^{th} stage and so forth. Increasing the number of clocks to equal the number of stages would not be beneficial as the spectral content of the clock would tend to approach that of a conventional synchronous logic system.

In a further embodiment the spacing between clocks need not be set nominally equally as in a preferred embodiment of the present invention where the spacing between clocks is set equally to the to the maximum propagation path in all combinatorial blocks. The delay between adjacent clocks need only be set to the maximum delay through the combinatorial blocks between the respective

DFF's.

In a further embodiment correlation in the spacing between clocks 391, 392, 393 and 394 may be reduced by insertion of random delays rather than fixed delays. For example noise can be added to modulate the threshold voltage of the delay elements and thereby modulate the delay period.

It has herein been shown that in a preferred embodiment of the present invention that the use of multiple clocks with fixed or varying spacing may be beneficial to randomising the position of current peaks and rendering said synchronous logic system more resistant to monitoring of the current or electromagnetic emissions as a means to determine the internal secrets of said synchronous logic system without the significant decrease in clock frequency that would occur in a prior art synchronous logic system.

We claim:

1. A synchronous logic device with enhanced security pertaining to a third party attempts in determining aspects of the internal operation or other aspects through monitoring of the current or electromagnetic emissions generated by state changes that occur at clock edge transitions comprising:
a. A logic system without a clock generator;
b. A clock generator producing a plurality of clock signals.

2. A logic system of claim 1.a comprising a. A plurality of state storage elements such as D-type flip-flops;
b. A plurality of combinatorial logic elements;
c. A plurality of logic delay elements;
d. Interconnection of said state storage elements, combinatorial logic elements and logic delay elements to implement a hardware time-driven algorithm;

3. A clock generator of claim 1.b in a first implementation comprising:
a. A first clock signal of period comprising a fixed part and a variable part;
b. A first clock signal of said clock signals of claim 3.a where the fixed period part is no less that the propagation delay through combinatorial logic elements of claim 2.b producing the largest propagation delay path between any two D-type flip-flops of claim 2.a;
c. Further clock signals of claim 3 each further clock signal delayed in time relative to every other further clock signal and to the first clock signal of claim 3.a by an amount no less than the maximum propagation delay through combinatorial logic elements of claim 2.b.

4. A clock generator of claim 1.b in a second implementation comprising:
a. A first clock signal of period comprising a fixed part and a variable part;
b. A first clock signal of said clock signals of claim 4.a where the fixed period part is no less that the propagation delay through combinatorial logic elements of claim 2.b producing the largest propagation delay path between any two D-type flip-flops of claim 2.a;
c. Further clock signals of claim 4 each further clock signal delayed in time relative to every other further clock signal and to the first clock signal of claim 4.a by a random amount wherein the minimum time between adjacent clock edges is no less than the maximum propagation delay through combinatorial logic elements of claim 2.b.

5. A clock generator of claim 1.b in a third implementation comprising:
a. A first clock signal of period comprising a fixed part and a variable part;
b. A first clock signal of said clock signals of claim 5.a where the fixed period part is no less that the propagation delay through combinatorial logic elements of claim 2.b producing the largest propagation delay path between any two D-type flip-flops of claim 2.a;
c. Further clock signals of claim 5 each further clock signal delayed in time relative to every other further clock signal and to the first clock signal of claim 5.a by an amount no less than the maximum propagation delay through combinatorial logic elements of claim 2.b wherein the number of clock signals is restricted to a number smaller than the number of pipelined stages within the logic system of claim 2 where each of the further clock signals may drive multiple stages of the logic system.

6. A method for performing synchronous logic operations with enhanced security pertaining to a third party attempts in determining aspects of the internal operation or other aspects through monitoring of the current or electromagnetic emissions generated by state changes that occur at clock edge transitions comprising:
a. A logic system without a clock generator;
b. A clock generator producing a plurality of clock signals.
